(19) United States
(12) Patent Application Publication
(10) Pub. No.: US 2025/0379143 A1
(43) Pub. Date: Dec. 11, 2025

(54) SEMICONDUCTOR DEVICE

(71) Applicant: SAMSUNG ELECTRONICS CO., LTD., Suwon-si (KR)

(72) Inventors: Sungwoo LEE, Suwon-si (KR); Wonhyuk HONG, Suwon-si (KR); Hoyun JEON, Suwon-si (KR); Eunji JUNG, Suwon-si (KR); Hyunjin JEONG, Suwon-si (KR)

(21) Appl. No.: 19/005,513

(22) Filed: Dec. 30, 2024

(30) Foreign Application Priority Data
Jun. 11, 2024 (KR) 10-2024-0075463

(51) Int. Cl. H01L 23/522; H01L 23/528

(52) U.S. Cl. CPC H01L 23/5228; H01L 23/5226; H01L 23/5283

(57) ABSTRACT

A semiconductor device includes: a lower structure; a base layer on the lower structure; a resistance structure including a first resistance conductive layer on the base layer and a second resistance conductive layer on the first resistance conductive layer, wherein the first resistance conductive layer and the second resistance conductive layer include different materials; an interlayer insulating layer on the resistance structure; and upper interconnection layers extending downwardly from an upper surface of the interlayer insulating layer. The upper interconnection layers are electrically connected to the resistance structure. Each of the upper interconnection layers includes a side surface and a bottom surface. The bottom surface of each of the upper interconnection layers is in contact with the first resistance conductive layer. A portion of the side surface of each of the upper interconnection layers is in contact with the second resistance conductive layer.

### CROSS-REFERENCE TO RELATED APPLICATION

This application claims benefit of priority to Korean Patent Application No. 10-2024-0075463, filed on Jun. 11, 2024, in the Korean Intellectual Property Office, the disclosure of which is incorporated herein by reference in its entirety.

### BACKGROUND

The present disclosure relates to a semiconductor device including a resistance structure.

A semiconductor device, such as a logic circuit and a memory, may include an interconnection structure in an upper portion and/or a lower portion of a portion of the semiconductor device, and the interconnection structure disposed in the lower portion may be referred to as a back-end-of-line (BEOL). The interconnection structure may include an interconnection connecting various conductive elements located on different levels, such as a contact plug connected to an active region (i.e., a conductive source or a conductive drain), and may further include resistance structures as a passive element in addition thereto.

### SUMMARY

One or more example embodiments provide a semiconductor device including a reliable interconnection structure.

One or more example embodiments provide a semiconductor device including a resistance structure that may secure contact reliability with interconnections while minimizing thermal resistivity of the resistance structure.

According to an aspect of an example embodiment, a semiconductor device includes: a lower structure; a base layer on the lower structure; a resistance structure including a first resistance conductive layer on the base layer and a second resistance conductive layer on the first resistance conductive layer, wherein the first resistance conductive layer and the second resistance conductive layer include different materials; an interlayer insulating layer on the resistance structure; and upper interconnection layers extending downwardly from an upper surface of the interlayer insulating layer. The upper interconnection layers are electrically connected to the resistance structure. Each of the upper interconnection layers includes a side surface and a bottom surface. The bottom surface of each of the upper interconnection layers is in contact with the first resistance conductive layer. A portion of the side surface of each of the upper interconnection layers is in contact with the second resistance conductive layer.

According to another aspect of an example embodiment, a semiconductor device includes: a base layer; a resistance structure including a first resistance conductive layer on the base layer and a second resistance conductive layer on the first resistance conductive layer, wherein the first resistance conductive layer and the second resistance conductive layer include different materials; an interlayer insulating layer on the resistance structure; and upper connection structures extending downwardly from an upper surface of the interlayer insulating layer, wherein the upper connection structures are electrically connected to the resistance structure. Each of the upper connection structures extends from through the second resistance conductive layer to the first resistance conductive layer, a side surface of each of the upper connection structures horizontally contacts the second resistance conductive layer, and a bottom surface of each of the upper connection structures vertically contacts the first resistance conductive layer.

According to another aspect of an example embodiment, a semiconductor device includes: a lower structure including a substrate, circuit elements, a lower insulating layer, and lower interconnection layers connected to the circuit elements; a resistance structure including a first resistance conductive layer on the lower structure and a second resistance conductive layer on the first resistance conductive layer, wherein the first resistance conductive layer and the second resistance conductive layer include different materials; an interlayer insulating layer on the resistance structure; and upper interconnection layers extending downwardly from an upper surface of the interlayer insulating layer, wherein the upper interconnection layers electrically connected to the lower interconnection layers or the resistance structure. Each of the upper interconnection layers includes a side surface and a bottom surface. The bottom surface of each of the upper interconnection layers connected to the resistance structure is in contact with the first resistance conductive layer. A portion of the side surface of each of the upper interconnection layers is in contact with the second resistance conductive layer. The bottom surface of each of the upper interconnection layers connected to the lower interconnection layers is in contact with an upper surface of each of the lower interconnection layers.

According to another aspect of an example embodiment, a method for manufacturing a semiconductor device, includes: sequentially stacking, on a lower structure, a base layer, a first conductive layer, a second conductive layer, a protective layer and a hard mask layer; forming a resistance structure by etching the protective layer, the second conductive layer, and the first conductive layer using the hard mask layer; forming an interlayer insulating layer to cover the resistance structure; forming an upper hard mask layer on the interlayer insulating layer; forming via holes exposing an upper surface of the protective layer of the resistance structure using the upper hard mask layer; exposing the first conductive layer by etching the protective layer and the second conductive layer from the via holes in a downward direction; and forming connection structures by filling the via holes with a conductive material. The second conductive layer, the hard mask layer, and the upper hard mask layer include a same material.

### BRIEF DESCRIPTION OF DRAWINGS

The above and other aspects, features, and advantages will be more apparent from the following description of example embodiments, taken in conjunction with the accompanying drawings, in which:

FIG. 1 is a plan view illustrating a semiconductor device according to example embodiments.

FIG. 2 is a cross-sectional view of the semiconductor device of FIG. 1 taken along line I-I′ according to example embodiments.

FIG. 3 is an enlarged cross-sectional view of a portion of the semiconductor device of FIG. 2 according to example embodiments.

FIGS. 4 to 8 are cross-sectional views illustrating semiconductor devices according to example embodiments.

FIGS. 9A, 9B, 9C, 9D, 9E, 9F, 9G, 9H, 9I, 9J, 9K and 9L are views illustrating a method for manufacturing the semiconductor device of FIG. 2 according to example embodiments.

### DETAILED DESCRIPTION

Hereinafter, example embodiments are described with reference to the accompanying drawings. Terms such as “upper,” “intermediate,” “lower,” and the like may be replaced with other terms, such as “first,” “second,” “third,” and the like, and may also be used to describe elements of the specification. Terms such as “first,” “second,” “third,” and the like may be used to describe various components, but components are not limited by the terms, and “first component” may be named “second component.” Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another example embodiment also provided herein or not provided herein but consistent with the present disclosure.

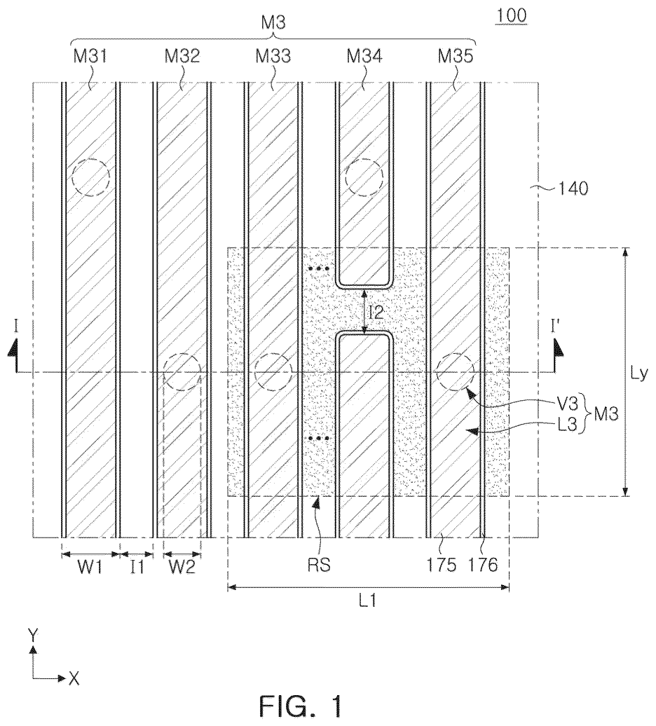

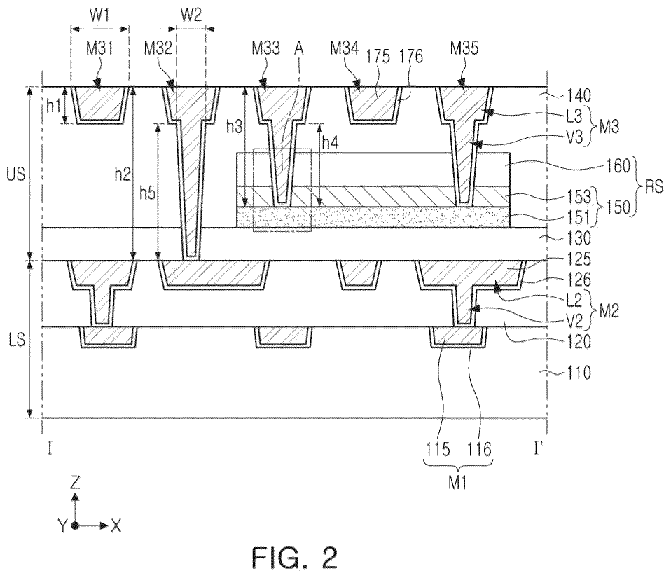

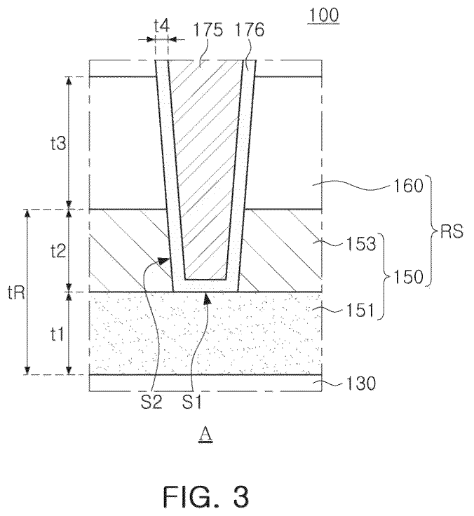

FIG. 1 is a plan view illustrating a semiconductor device according to example embodiments, FIG. 2 is a cross-sectional view of the semiconductor device of FIG. 1 taken along line I-I′, and FIG. 3 is an enlarged cross-sectional view of a portion of the semiconductor device of FIG. 2. FIG. 2 illustrates a cross-section of the semiconductor device of FIG. 1 taken along line I-I′, and FIG. 3 is an enlarged view of portion ‘A’ of FIG. 2. For convenience of explanation, only some components of a semiconductor device are illustrated in FIGS. 1 to 3.

Referring to FIGS. 1 to 3, a semiconductor device 100 may include a lower structure LS and an upper structure US on the lower structure LS. The lower structure LS may include at least two layers of lower interconnection layers M1 and M2, and the upper structure US may be disposed on uppermost lower interconnection layers M2 of the lower structure LS to overlap the lower structure LS in a Z-direction.

The lower structure LS may include a lower substrate 110, at least two layers of lower interconnection layers M1 and M2 on the lower substrate 110, and a lower insulating layer 120.

The lower substrate 110 may have an upper surface extending in an X-direction and a Y-direction. The lower substrate 110 may include an insulating material. For example, the lower substrate 110 may include a flowable oxide (FOX), a Tonen silazen (TOSZ), an undoped silica glass (USG), a borosilica glass (BSG), a phosphosilaca glass (PSG), a borophosphosilica glass (BPSG), a plasma enhanced tetraethylorthosilicate (PETEOS), a fluoride silicate glass (FSG), a high density plasma (HDP) oxide, a plasma enhanced oxide (PEOX), a flowable CVD (FCVD) oxide, or a combination thereof.

First lower interconnection layers M1 may be arranged on the lower substrate 110. The first lower interconnection layers M1 may be embedded in the lower substrate 110 such that an upper surface thereof may be exposed on the lower substrate 110, and may extend in the X-direction or the Y-direction.

The first lower interconnection layers M1 may include at least one of titanium nitride (TiN), tantalum nitride (TaN), tungsten nitride (WN), tungsten carbon nitride (WCN), copper (Cu), aluminum (Al), cobalt (Co), titanium (Ti), tantalum (Ta), nickel (Ni), tungsten (W), molybdenum (Mo), platinum (Pt), ruthenium (Ru), or iridium (Ir).

Each of the first lower interconnection layers M1 may include a barrier layer 116 and a conductive layer 115 disposed on the barrier layer 116. The barrier layer 116 may include a metal nitride, and according to an example embodiment, the barrier layer 116 may include titanium nitride (TiN). The conductive layer 115 may include a metal material, and according to an example embodiment, the conductive layer 115 may include copper (Cu).

A lower insulating layer 120 covering the first lower interconnection layers M1 may be disposed on the lower substrate 110. The lower insulating layer 120 may include at least one of a low-κ dielectric, an oxide, a nitride, or an oxynitride, and may include silicon oxide, silicon oxynitride, SiOC, SiCOH, or a combination thereof. A low-κ dielectric may be a material having a lower dielectric constant than silicon oxide (e.g., SiO₂). According to an example embodiment, the lower insulating layer 120 may include porous silicon oxide having voids.

Second lower interconnection layers M2 may be disposed on the lower insulating layer 120. The second lower interconnection layers M2 may be uppermost lower interconnection layers in the lower structure LS, and may have an upper surface, coplanar with the lower insulating layer 120. The second lower interconnection layers M2 may include a plurality of interconnection patterns, and the interconnection patterns may extend in the X-direction or the Y-direction according to a circuit design. The second lower interconnection layers M2 may include an interconnection portion L2 and a via portion V2, and a portion of the second lower interconnection layers M2 may include only the interconnection portion L2, and a remaining portion thereof may include the via portion V2 extending below the interconnection portion L2. The interconnection portion L2 may be coplanar with an upper surface of the lower insulating layer 120, may extend in the X-direction or the Y-direction, and may be buried within the lower insulating layer 120 in a predetermined depth. The via portion V2 may extend from a lower surface of the interconnection portion L2, may have a width, narrower than a width of the lower surface of the interconnection portion L2, and may extend in the Z-direction to contact the upper surface of the first lower interconnection layers M1. The interconnection portion L2 may have a width decreasing from the upper surface thereof to a lower surface thereof (i.e., the interconnection portion L2 may be wider at the upper surface than at the lower surface), and the via portion V2 may also have a width decreasing from an upper surface thereof to the lower surface thereof (i.e., the via portion V2 may be wider at the upper surface than at the lower surface).

The second lower interconnection layers M2 including the interconnection portion L2, and the via portion V2, extending therefrom, may be manufactured using a dual damascene process, but are not limited thereto.

The second lower interconnection layers M2 may also include at least one of titanium nitride (TiN), tantalum nitride (TaN), tungsten nitride (WN), tungsten carbon nitride (WCN), copper (Cu), aluminum (Al), cobalt (Co), titanium (Ti), tantalum (Ta), nickel (Ni), tungsten (W), molybdenum (Mo), platinum (Pt), ruthenium (Ru), or iridium (Ir).

Each of the second lower interconnection layers M2 may include a barrier layer 126 and a conductive layer 125 disposed on the barrier layer 126. The barrier layer 126 may include a metal nitride, and according to an example embodiment, the barrier layer 126 may include titanium nitride (TiN). The conductive layer 125 may include a metal material, and according to an example embodiment, the conductive layer 125 may include copper (Cu). The barrier layer 126 may be disposed on side and bottom surfaces of the second lower interconnection layers M2, and the conductive layer 125 may be surrounded by the barrier layer 126.

When the second lower interconnection layers M2 include both the interconnection portion L2 and the via portion V2, the barrier layer 126 may not be disposed on a boundary between the interconnection portion L2 and the via portion V2.

An upper surface of the lower insulating layer 120 and the upper surfaces of the second lower interconnection layers M2 may be coplanar, and may form an upper surface of the lower structure LS, and the upper structure US may be disposed on the upper surface of the lower structure LS.

The upper structure US may include a base layer 130, a resistance structure RS on the base layer 130, an interlayer insulating layer 140 covering the resistance structure RS and the base layer 130, and upper interconnection layers M3 within the interlayer insulating layer 140.

The base layer 130 may be disposed to cover the upper surface of the lower structure LS. The base layer 130 may be an insulating layer, may include at least one of an oxide, a nitride, a carbide, or an oxynitride, and may include silicon oxide, silicon oxynitride, SiOC, SiCOH, SiCN, or a combination thereof.

At least one resistance structure RS may be disposed on the base layer 130. The resistance structure RS may be designed to have a resistance value of a predetermined size as a passive element in the semiconductor device 100. Such a resistance structure RS may be a thin film resistor (TFR), and may include at least two metal layers 150 (151 and 153) connected between two terminals.

The resistance structure RS may have a plate shape extending in the X-direction and the Y-direction and having a predetermined area, and a first length L1 in the X-direction may cross approximately 5 to 500 upper interconnection patterns M3, and a length Ly in the Y-direction may be the same as or shorter than the first length L1. For example, the length Ly in the Y-direction may correspond to a length that crosses 250 or fewer upper interconnection patterns M3, but is not limited thereto.

In an example embodiment, a metal layer 150 of the resistance structure RS may include a first resistance conductive layer 151 and a second resistance conductive layer 153, having a plate form extending in the X-direction and the Y-direction and having a predetermined area. The first resistance conductive layer 151 may be disposed on the base layer 130, and a lower surface of the second resistance conductive layer 153 may be arranged to directly contact an upper surface of the first resistance conductive layer 151. The first resistance conductive layer 151 may be between the base layer 130 and the second resistance conductive layer 153. An area of the second resistance conductive layer 153 may be equal to or smaller than an area of the first resistance conductive layer 151, but is not limited thereto. A side surface of the second resistance conductive layer 153 may be aligned with a side surface of the first resistance conductive layer 151 in the Z-direction, but is not limited thereto. The first resistance conductive layer 151 and the second resistance conductive layer 153 may include different conductive materials, and a first material forming the first resistance conductive layer 151 and a second material forming the second resistance conductive layer 153 may have opposite gradient directions (polarities) of thermal resistance (temperature coefficient resistance (TCR)). For example, the first material may have a negative slope in thermal resistance, and the second material may have a positive slope in thermal resistance. A negative slope in thermal resistance may indicate that a material has a resistance value which decreases as a temperature increases, and a positive slope in thermal resistance may indicate that a material has a resistance value which increases as a temperature increases. In terms of reliability of a passive element, it is desirable that the resistance value does not vary depending on the temperature and that the slope converges to 0. Therefore, the metal layer 150 of the resistance structure RS may be disposed to contact two conductive layers (151 and 153) having thermal resistance slopes in different directions with each other, such that a composite thermal resistance (total TCR) approaches 0. Therefore, the resistance structure RS may exhibit a predetermined element resistance regardless of a temperature.

For example, the first material of the first resistance conductive layer 151 may include tantalum nitride (TaN), and the second material of the second resistance conductive layer 153 may include titanium nitride (TiN), but are not limited thereto.

The first resistance conductive layer 151 may have a first thickness t1, and the second resistance conductive layer 153 may have a second thickness t2, substantially the same as the first thickness t1. A total sum of the first thickness t1 and the second thickness t2 may form a total thickness tR of the metal layer 150 of the resistance structure RS, and element resistance of the resistance structure RS may be determined according to the total thickness tR and an overlapping area of the first resistance conductive layer 151 and the second resistance conductive layer 153.

The total thickness tR of the metal layer 150 may be within a range of 80 nm to 100 nm, and preferably may be 90 nm. In this case, the first thickness t1 and the second thickness t2 may be within a range of 40 nm to 50 nm, respectively, but are not limited thereto.

The resistance structure RS may further include a protective layer 160 on the second resistance conductive layer 153. The protective layer 160 may include a material, identical to a material of the base layer 130, and as an insulating layer, may include at least one of an oxide, a nitride, a carbide, or an oxynitride, and may include silicon oxide, silicon oxynitride, SiOC, SiCOH, SiCN, or a combination thereof.

Preferably, the base layer 130 and the protective layer 160 may include SiCN, and may have substantially the same thickness, but are not limited thereto. The thickness of the protective layer 160 may include a third thickness t3, greater than the second thickness t2 of the second resistance conductive layer 153, and the protective layer 160 may be disposed to overlap in the Z-direction on an upper surface of the second resistance conductive layer 153, to have an area, substantially equal to an area of the first resistance conductive layer 151. A side surface of the protective layer 160 and the side surface of the first resistance conductive layer 151 may be aligned in the Z-direction, but are not limited thereto.

The interlayer insulating layer 140 may be disposed to cover an upper surface and a side surface of the resistance structure RS, cover an upper surface of the base layer 130, and have an upper surface, and be spaced apart from an upper surface of the protective layer 160 of the resistance structure RS by a predetermined distance or more. Because the interlayer insulating layer 140 may be spaced apart from the upper surface of the protective layer 160 by a predetermined distance or more, a distance from the upper surface of the base layer 130 to the upper surface of the interlayer insulating layer 140 may be greater than a distance from the upper surface of the protective layer 160 to the upper surface of the interlayer insulating layer 140.

The interlayer insulating layer 140 may include a low-κ dielectric or an ultra-low-κ dielectric (ULK), may include at least one of an oxide, a nitride, or an oxynitride, and may include silicon oxide, silicon oxynitride, SiOC, SiCOH, or a combination thereof.

The upper interconnection layers M3 may be disposed on the upper surface of the interlayer insulating layer 140.

The upper interconnection layers M3 may include a plurality of upper interconnection patterns (M31 to M35) extending in the Y-direction, as illustrated in FIG. 1, and each of the upper interconnection patterns (M31 to M35) may be spaced apart from each other in the X-direction. Widths W1 of the upper interconnection patterns (M31 to M35) in the X-direction may be within a range of 35 nm to 45 nm, and may preferably be 40 nm, respectively, and a separation distance I1 in the X-direction may be within a range of 35 nm to 40 nm. Depending on a circuit design, some of the upper interconnection patterns (M31 to M35) may include two patterns that may be cut from each other in the Y-direction and spaced apart in the Y-direction by a separation distance I2. The separation distance I2 may be, for example, within a range of 35 nm to 40 nm.

In FIG. 1, the upper interconnection patterns (M31 to M35) extending in the Y-direction may be named from the left as a first upper interconnection pattern M31, a second upper interconnection pattern M32, a third upper interconnection pattern M33, a fourth upper interconnection pattern M34, and a fifth upper interconnection pattern M35, and thereamong, for example, the fourth upper interconnection pattern M34, may be cut in the Y-direction to include two patterns that are separated by the separation distance I2.

In FIG. 1, the first to fifth upper interconnection patterns M31 to M35 are illustrated as upper interconnection patterns (M31 to M35) in a continuous order, but are not limited thereto, and a plurality of upper interconnection patterns (M31 to M35) may be disposed between the first to fifth upper interconnection patterns M31 to M35. Therefore, the first length L1 of the resistance structure RS in the X-direction and the length Ly of the resistance structure RS in the Y-direction are not limited by the number of upper interconnection patterns (M31 to M35) of FIG. 1.

The upper interconnection patterns (M3: M31 to M35) may include an interconnection portion L3 and a via portion V3. The interconnection portion L3 may be disposed on all of the first to fifth upper interconnection patterns (M3: M31 to M35), and may extend in the Z-direction by a first depth h1 from the upper surface of the interlayer insulating layer 140. Widths W1 of upper surfaces of a plurality of interconnection portions L3 may be the same, and a width W1 of an upper surface of the interconnection portion L3 may be substantially defined as a first width W1 of the upper interconnection layers M3. A width of a lower surface of the interconnection portion L3 may be narrower than the width W1 of the upper surface, and the interconnection portion L3 may have an inclined side surface between the upper surface and the lower surface.

A portion of the first to fifth upper interconnection patterns (M3: M31 to M35) may further include the via portion V3 below the interconnection portion L3. The via portion V3 may have a cross-section in the form of a circle, an ellipse, a tetragon, etc., and may extend downward in the Z-direction from the lower surface of the interconnection portion L3 to contact a different interconnection layer (M2) or the resistance structure RS.

The via portion V3 may have a width W2 of an upper surface, narrower than the width W1 of the upper surface of the interconnection portion L3, and the via portion V3 may have a width decreasing from the upper surface to the lower surface (i.e., the via portion V2 may be wider at the upper surface than at the lower surface), and may have an inclined side surface between the upper surface and the lower surface.

The upper interconnection patterns (M3: M31 to M35) may include via portions V3 having different lengths (h4 and h5), depending on an object to be contacted.

At least one of the upper interconnection patterns (M3: M31 to M35) may extend through the interlayer insulating layer 140 and the base layer 130 to contact the upper surface of the uppermost lower interconnection layers M2 of the lower structure LS. Therefore, the second upper interconnection pattern M32, which may be at least one of the upper interconnection patterns (M3: M31 to M35), may have a length h2 corresponding to a thickness from the upper surface of the interlayer insulating layer 140 to the lower surface of the base layer 130, and the via portion V3 of the second upper interconnection pattern M32 may extend from a lower surface of the interconnection portion L3 by a predetermined length h5, such that a bottom surface is coplanar with a lower surface of the upper structure US.

At least two of the upper interconnection patterns (M3: M31 to M35) may extend to the upper surface of the first resistance conductive layer 151 of the resistance structure RS among the lower structures LS. For example, the third upper interconnection pattern M33 and the fifth upper interconnection pattern M35 may have the via portion V3 disposed below the interconnection portion L3, respectively, and the via portion V3 may have a fourth length h4 extending in the Z-direction from the lower surface of the interconnection portion L3 to the upper surface of the first resistance conductive layer 151. The via portions V3 of the third upper interconnection pattern M33 and the fifth upper interconnection pattern M35 may penetrate the interlayer insulating layer 140, may penetrate the protective layer 160, may penetrate the second resistance conductive layer 153, may be in contact with the upper surface of the first resistance conductive layer 151 below the second resistance conductive layer 153, and may be electrically connected with the first resistance conductive layer 151 and the second resistance conductive layer 153. The side surface of the via portion V3 may have a continuous inclined surface having a constant slope from the upper surface to the lower surface, without a bending portion, while continuously penetrating different materials.

A bottom surface S1 of the via portions V3 of the third upper interconnection pattern M33 and the fifth upper interconnection pattern M35 may vertically contact the upper surface of the first resistance conductive layer 151, and a portion of the side surface of the via portion V3, specifically, a lower region S2 bent from the bottom surface S1, may horizontally contact the second resistance conductive layer 153. An area of the bottom surface S1 of the via portion V3 that contacts the first resistance conductive layer 151 may be smaller than or equal to an area of a portion (S2) of the side surface of the via portion V3 that contacts the second resistance conductive layer 153. Contact between the via portions V3 of the third upper interconnection pattern M33 and the fifth upper interconnection pattern M35 and the resistance structure RS may occur simultaneously in a portion of the first resistance conductive layer 151 and a portion of the second resistance conductive layer 153 to increase a contact area, and three-dimensional contact may prevent defects such as misalignment, short circuit, or the like occurring in the contact. In addition, because the first resistance conductive layer 151 and the second resistance conductive layer 153 include different materials and have different levels of etching selectivity, etching of a via hole may be stopped by the first resistance conductive layer 151 without separately including an etching stopper, when forming the via hole. Therefore, when the resistance structure RS is formed as a single layer, defects of punching-through when forming the via hole may be resolved.

The upper surface of the via portion V3 may have a width W2 of 15 nm to 25 nm, preferably 20 nm, which may be narrower than the width W1 of the upper surface of the interconnection portion L3, and narrower than the width of the lower surface of the interconnection portion L3. The upper surface of the via portion V3 may be disposed within a range of the lower surface of the interconnection portion L3 to overlap the lower surface of the interconnection portion L3 in the Z-direction, and a center of the interconnection portion L3 and a center of the via portion V3 may form the same axis.

The upper interconnection layer M3 may include a conductive layer 175 and a barrier layer 176 covering a side surface and a bottom surface of the conductive layer 175. The conductive layer 175 may include Cu, and the barrier layer 176 may include at least one of titanium (Ti), tantalum (Ta), titanium nitride (TiN), or tantalum nitride (TaN), but may include tantalum nitride (TaN), the same as the first resistance conductive layer 151.

In a case in which the via portion V3 is connected below the interconnection portion L3 of the upper interconnection layer M3, the barrier layer 176 may not be disposed between a boundary between the interconnection portion L3 and the via portion V3, for example, between the upper surface of the via portion V3 and the lower surface of the interconnection portion L3. Therefore, the interconnection portion L3 and the via portion V3 form a continuous structure, and the barrier layer 176 may be formed on the side and bottom surfaces, and the conductive layer 175 may be surrounded by the barrier layer 176. A thickness t4 of the barrier layer 176 of the upper interconnection layer M3 may be 2 to 4 nm, preferably 3 nm, but is not limited thereto.

In this manner, a portion of the upper interconnection layers M3 may include the first upper interconnection pattern M31 and the fourth upper interconnection pattern M34, only including the interconnection portion L3. The upper interconnection layer M3 may include the second upper interconnection pattern M32 including the via portion V3 that extends toward the upper surface of the upper interconnection layer M2, which is located on the uppermost position, of the lower structure LS below the interconnection portion L3. A portion of the upper interconnection layers M3 may include third and fifth upper interconnection patterns (M33 and M35) that include the via portion V3 that extends toward the upper surface of the first resistance conductive layer 151 of the resistance structure RS below the interconnection portion L3.

In this manner, the upper surfaces of the upper interconnection patterns (M3: M31 to M35) having different lengths may be exposed to be coplanar with the upper surface of the interlayer insulating layer 140, widths W1 of the upper surfaces of the exposed upper interconnection patterns (M3: M31 to M35) may be the same as each other, and separation distances I1 may also be the same as each other, but are not limited thereto.

Each of the third upper interconnection pattern M33 and the fifth upper interconnection pattern M35, connected to the resistance structure RS, may function as terminals of the resistance structure RS, and may be electrically and physically connected to the resistance structure RS to allow current to flow.

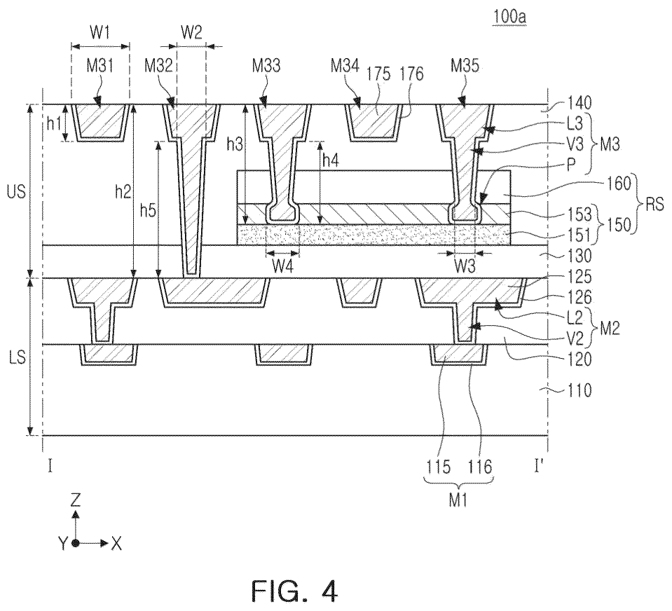

FIGS. 4 to 8 are cross-sectional views illustrating semiconductor devices according to example embodiments.

Referring to FIG. 4, a semiconductor device 100a may be the same as the semiconductor device 100 of FIGS. 1 to 3, except that lower ends of upper interconnection patterns (M33 and M35) connected to a resistance structure RS, among upper interconnection patterns (M3: M31 to M35) of an upper interconnection layer M3, include a connection portion P.

In the semiconductor device 100a of FIG. 4, third and fifth upper interconnection patterns M33 and M35 connected to the resistance structure RS, among the upper interconnection patterns (M3: M31 to M35), may further include the connection portion P below a via portion V3.

The via portion V3 may have a decrease in width from an upper portion to a lower portion, and may have a side surface having a continuous slope. In this case, the connection portion P may further be included below the via portion V3. The connection P may be defined as a region penetrating a second resistance conductive layer 153 from an upper surface of the second resistance conductive layer 153 below the via portion V3, and may be a region extending from the via portion V3 to an upper surface of a first resistance conductive layer 151. The connection P may expand a width below the via portion V3 to have a width W4, greater than a width W3 of a lower end of the via portion V3, and may include a side surface that may be bent to contact a side surface of the second resistance conductive layer 153 on the inclined side surface of the via portion V3 by the expanded width W4.

The width W4 of the connection P may be constant from an upper portion to a lower portion, but may decrease toward the lower portion within a predetermined range. Even though the width decreases, a width of a lower surface may be greater than the width W3 of the lower portion of the via portion V. In this manner, the connection portion P may be defined as a portion of which width W4 is expanded from the via portion V3, and an area of a bottom surface S1 of the connection portion P contacting the first resistance conductive layer 151 may be greater than an area of the bottom surface S1 of the via portion V3 of FIG. 3. A contact area of a side surface S2 of the connection portion P with the second resistance conductive layer 153 may be substantially the same as a contact area of the contacting side surface S2 of the via portion V3 of FIG. 3. Therefore, contact resistance may be reduced, such that heat generation in a contact region may be minimized. A barrier layer 176 may be disposed along side and bottom surfaces of an interconnection portion L3, the via portion V3, and the connection portion P, and a conductive layer 175 may be surrounded by the barrier layer 176. A thickness and a material of the barrier layer 176 and a thickness and a material of the conductive layer 175 may be the same as those of the semiconductor device 100 of FIG. 3.

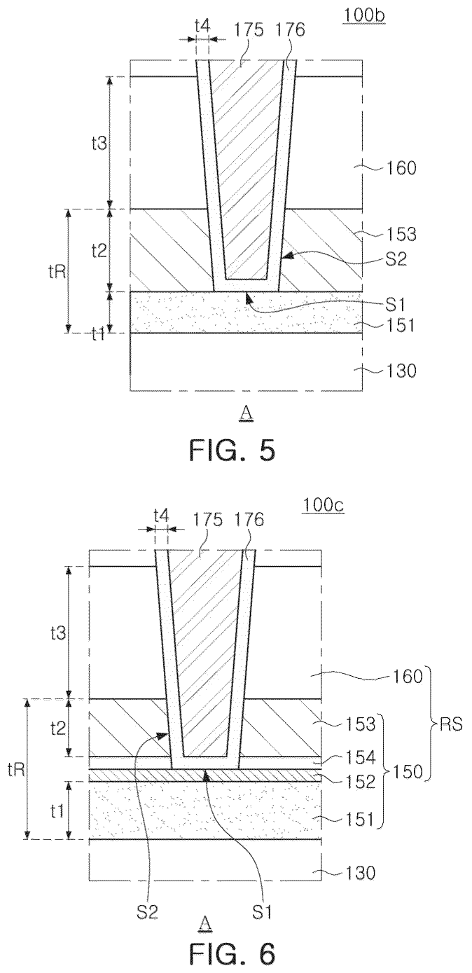

Referring to FIG. 5, a semiconductor device 100b may be the same as the semiconductor device 100 of FIGS. 1 to 3, except for a thickness of a first resistance conductive layer 151 and a thickness of a second resistance conductive layer 153 in a resistance structure RS.

In the resistance structure RS, a lower surface of the second resistance conductive layer 153 may be disposed in direct contact with an upper surface of the first resistance conductive layer 151. An area of the second resistance conductive layer 153 may be the same as or smaller than an area of the first resistance conductive layer 151, but is not limited thereto. The first resistance conductive layer 151 and the second resistance conductive layer 153 may include different metal materials, and a first material forming the first resistance conductive layer 151 and a second material forming the second resistance conductive layer 153 may have opposite directions of thermal resistance (TCR). For example, the first material may have a negative slope in thermal resistance, and the second material may have a positive slope in thermal resistance. Two material layers having different directions of thermal resistance may be arranged to be in contact with each other, such that a composite thermal resistance approaches 0. Therefore, the resistance structure RS may exhibit a predetermined element resistance regardless of a temperature.

The first material may include tantalum nitride, and the second material may include titanium nitride, but are not limited thereto.

The first resistance conductive layer 151 may have a first thickness t1, and the second resistance conductive layer 153 may have a second thickness t2, substantially greater than the first thickness t1. A total sum of the first thickness t1 and the second thickness t2 may form a total thickness tR of a conductive layer of the resistance structure RS, and element resistance of the resistance structure RS may be determined according to the total thickness tR and an overlapping area of the first resistance conductive layer 151 and the second resistance conductive layer 153.

The total thickness tR of the conductive layer may be within a range of 80 nm to 100 nm, and preferably may be about 90 nm. In this case, the second thickness t2 may be twice the first thickness t1, and may be disposed such that the first thickness t1 is about 30 nm and the second thickness t2 is about 60 nm, but are not limited thereto.

When comparing absolute values of slopes of thermal resistance, an absolute value of a slope of thermal resistance of the titanium nitride (TiN) of the second resistance conductive layer 153 may be less than an absolute value of a slope of thermal resistance of the tantalum nitride (TaN) of the first resistance conductive layer 151. Therefore, the second thickness t2 of the second resistance conductive layer 153 may be formed to be greater, titanium nitride having a positive thermal resistance may be included in greater amounts to minimize influence of the tantalum nitride having a greater absolute value of the slope of the thermal resistance. Therefore, the composite thermal resistance may converge more to 0, thereby further securing element reliability of the resistance structure RS. In addition, in a via portion V3 of upper interconnection layers M3, an area of a side surface S2 contacting the second resistance conductive layer 153 may be greater than an area of a bottom surface S1 contacting the first resistance conductive layer 151.

Referring to FIG. 6, a semiconductor device 100c may be the same as the semiconductor device 100 of FIGS. 1 to 3, except that a first conductive layer 152 and a second conductive layer 154 are further included between a first resistance conductive layer 151 and a second resistance conductive layer 153 of a resistance structure RS.

The first conductive layer 152 may be disposed on an upper surface of the first resistance conductive layer 151, may have an area, equal to an area of the first resistance conductive layer 151, and may be a metal layer including tantalum, when the first resistance conductive layer 151 is formed of tantalum nitride.

The first conductive layer 152 may have a thickness, significantly less than a thickness of the first resistance conductive layer 151, and may include a thickness of ⅕ to 1/10 of a first thickness t1.

The second conductive layer 154 may be disposed between an upper surface of the first conductive layer 152 and a lower surface of the second resistance conductive layer 153, may have an area, equal to an area of the first conductive layer 152, and may be a metal layer including titanium, when the second resistance conductive layer 153 is formed of titanium nitride.

The second conductive layer 154 may have a thickness, significantly less than a thickness of the second resistance conductive layer 153, and may include a thickness of ⅕ to 1/10 of a second thickness t2.

In this manner, the first conductive layer 152 and the second conductive layer 154 may be stacked between the first resistance conductive layer 151 and the second resistance conductive layer 153, and the first conductive layer 152 may be formed only of a metal component, identical to a metal component of a metal nitride of the first resistance conductive layer 151, and the second conductive layer 154 may be formed only of a metal component, identical to a metal component of a metal nitride of the second resistance conductive layer 153.

The resistance structure RS may further include a protective layer 160 on the second resistance conductive layer 153. The protective layer 160 may include a material, identical to a material of a base layer 130, and may include at least one of an oxide, a nitride, a carbide, or an oxynitride, and may include silicon oxide, silicon oxynitride, SiOC, SiCOH, SiCN, or a combination thereof.

In this case, a via portion V3 of upper interconnection patterns (M33 and M35) electrically connected to the resistance structure RS may penetrate the interlayer insulating layer 140, may penetrate the protective layer 160, may penetrate the second resistance conductive layer 153, and may penetrate the second conductive layer 154 to contact the upper surface of the first conductive layer 152.

In this case, a barrier layer 176 of the via portion V3 and the first resistance conductive layer 151, equally above and below the first conductive layer 152, may include tantalum nitride, such that the first conductive layer 152 may include tantalum. Therefore, contact resistance may be significantly reduced.

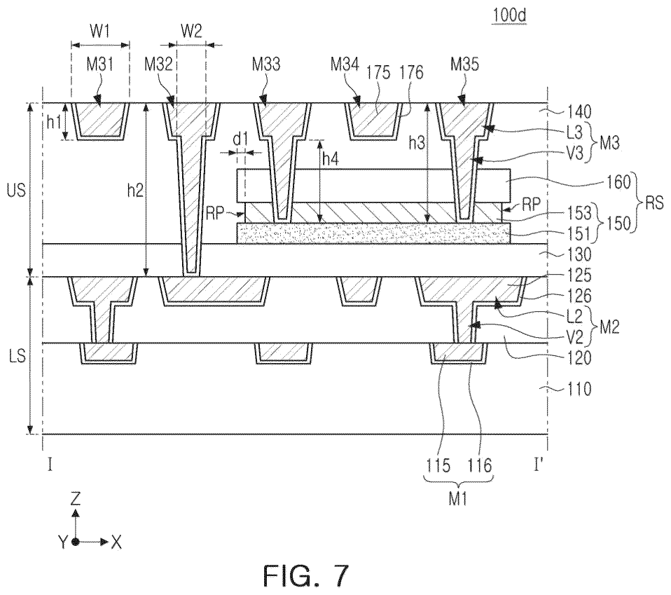

Referring to FIG. 7, a semiconductor device 100d may be the same as the semiconductor device 100 of FIGS. 1 to 3, except for an area of a first resistance conductive layer 151 and an area of a second resistance conductive layer 153 in a resistance structure RS.

When the second resistance conductive layer 153 is disposed on an upper surface of the first resistance conductive layer 151 of the resistance structure RS, the second resistance conductive layer 153 may be disposed to have a smaller area than the first resistance conductive layer 151.

For example, the second resistance conductive layer 153 may be formed to recess an edge region thereof on the first resistance conductive layer 151 by a first distance d1. Therefore, the second resistance conductive layer 153 may be formed to have a width difference by twice the first distance d1 than the first resistance conductive layer 151. When the first resistance conductive layer 151 is formed of tantalum nitride, the second resistance conductive layer 153 may include titanium nitride.

A protective layer 160 on the second resistance conductive layer 153 may include SiCN, and may have an area, equal to the area of the first resistance conductive layer 151.

Therefore, a side surface of the first resistance conductive layer 151 and a side surface of the protective layer 160 may be disposed in a straight line in the Z-direction, but the second resistance conductive layer 153 may be recessed inward by the first distance d1 to include a recessed portion RP, and may overlap the first resistance conductive layer 151 and the protective layer 160 in the Z-direction. The recessed portion RP of the second resistance conductive layer 153 may be formed during a manufacturing process when a hard mask for forming an upper interconnection layer M3 and the resistance structure RS includes the same material as the second resistance conductive layer 153, and a portion of the second resistance conductive layer 153 may be etched together when the hard mask is removed.

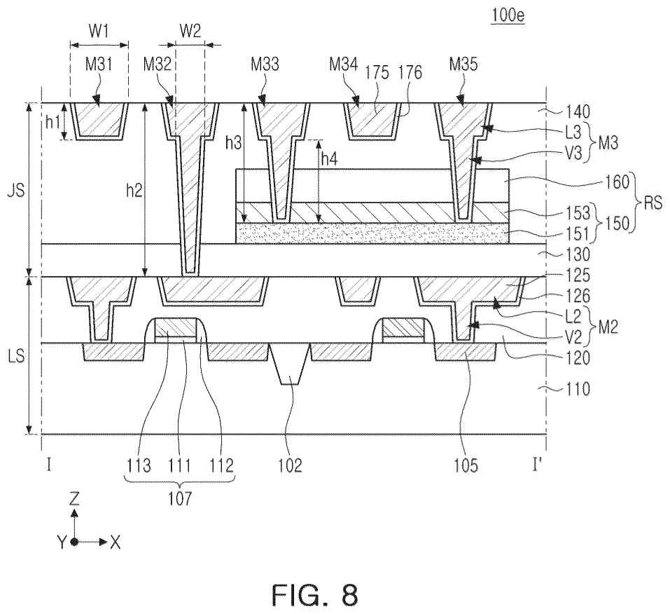

Referring to FIG. 8, a semiconductor device 100e may be the same as the first to third semiconductor devices 100 of FIGS. 1 to 3, except that a lower structure LS includes circuit elements.

The lower structure LS may include at least one lower interconnection layer M2, and an upper structure US may be disposed above the lower interconnection layers M2 of the lower structure LS to overlap the lower structure LS in the Z-direction.

The lower structure LS may include a lower substrate 110, a plurality of circuit elements 107 on the lower substrate 110, a plurality of element isolation regions 102. The lower structure LS may also include the at least one lower interconnection layer M2 and a lower insulating layer 120, connected to the circuit elements 107.

The lower substrate 110 may have an upper surface extending in the X-direction and the Y-direction. The lower substrate 110 may include a semiconductor material, such as a group IV semiconductor, a group III-V compound semiconductor, or a group II-VI compound semiconductor. For example, the group IV semiconductor may include silicon, germanium, or silicon-germanium. The lower substrate 110 may be provided as a bulk wafer, an epitaxial layer, a silicon-on-insulator (SOI) layer, or a semiconductor-on-insulator (SeOI) layer.

The lower substrate 110 may include the element isolation regions 102 for defining active regions arranged in an upper portion thereof. The active regions may include a channel region and a source/drain region of a transistor. Each of the active regions may include an impurity region. The impurity region may form at least a portion of a well region of the transistor. An element isolation region 102 may be located between the active regions.

The element isolation region 102 may fill a space between the active regions, and may define the active regions in the lower substrate 110. The element isolation region 102 may be formed, for example, by a shallow trench isolation (STI) process. The element isolation region 102 may expose an upper surface of an active region. The element isolation region 102 may be formed of an insulating material. The element isolation region 102 may include, for example, an oxide, a nitride, or a combination thereof.

The circuit elements 107 may be disposed between the element isolation regions 102. The circuit elements 107 may include a planar transistor. Each of the circuit elements 107 may include a gate dielectric layer 111, a spacer layer 112, and a gate electrode 113. Gate dielectric layers 111 may be disposed between the active region and the gate electrode 113 and between the channel region and the gate electrode 113, and may be disposed to cover at least a portion of surfaces of the gate electrode 113. The gate dielectric layer 111 may include an oxide, a nitride, or a high-κ material. The high-κ material may be a dielectric material having a higher dielectric constant than a silicon oxide (SiO₂). The high-κ dielectric material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). According to example embodiments, the gate dielectric layer 111 may be formed as a multilayer structure.

The gate electrode 113 may include a conductive material, and may include, for example, a metal nitride such as titanium nitride (TiN), tantalum nitride (TaN), or tungsten nitride (WN), and/or a metal material such as aluminum (Al), tungsten (W), molybdenum (Mo), or the like, or a semiconductor material such as doped polysilicon. According to example embodiments, the gate electrode 113 may be formed as a multilayer structure. Spacer layers 112 may be disposed on both side surfaces of the gate electrode 113 in the channel region. The spacer layers 112 may insulate source/drain regions and gate electrodes 113. According to example embodiments, shapes of upper ends of the spacer layers 112 may be variously changed, and the spacer layers 112 may be formed as a multilayer structure. The spacer layers 112 may include at least one of an oxide, a nitride, or an oxynitride, and may be formed as, for example, a low-κ dielectric film.

A source/drain region may be disposed in the lower substrate 110 on both sides of the gate electrode 113.

The lower insulating layer 120 may be disposed to cover the circuit elements 107 and the lower substrate 110. The lower insulating layer 120 may include at least one of a low-κ dielectric, an oxide, a nitride, or an oxynitride, and may include silicon oxide, silicon oxynitride, SiOC, SiCOH, or a combination thereof. The low-κ dielectric may be a material having a lower dielectric constant than silicon oxide (e.g., SiO₂). According to an example embodiment, an interlayer insulating layer 140 may include porous silicon oxide having pores.

The lower interconnection layers M2 may be disposed on the lower insulating layer 120. Upper surfaces of the lower interconnection layers M2 may be coplanar with the lower insulating layer 120.

The lower interconnection layers M2 may include a plurality of lower interconnection patterns, and the lower interconnection patterns may extend in the X-direction or the Y-direction according to a circuit design thereof. The lower interconnection patterns may include an interconnection portion L2 and a via portion V2, and a portion of the lower interconnection layers M2 may include only the interconnection portion L2, and a remaining portion thereof may include the via portion V2 extending downwardly from the interconnection portion L2.

The interconnection sections L2 may be coplanar with an upper surface of the lower insulating layer 120, and may extend while being buried within the lower insulating layer 120 to a predetermined depth. The via portion V2 may extend from a lower surface of the interconnection portion L2, and may extend toward the source/drain region or the gate electrode 113 of the circuit elements 107 to have a width, narrower than a width of the lower surface of the interconnection portion L2. The width of the interconnection portion L2 may decrease from the upper surface to the lower surface, and the width of the via portion V2 may also decrease from the upper surface to the lower surface. The lower interconnection layers M2 including the via portion V2 extending from the interconnection portion L2 may be manufactured by a dual damascene method, but is not limited thereto.

The lower interconnection layers M2 may include at least one of titanium nitride (TiN), tantalum nitride (TaN), tungsten nitride (WN), tungsten carbon nitride (WCN), copper (Cu), aluminum (Al), cobalt (Co), titanium (Ti), tantalum (Ta), nickel (Ni), tungsten (W), molybdenum (Mo), platinum (Pt), ruthenium (Ru), or iridium (Ir).

Each of the lower interconnection layers M2 may include a barrier layer 126 and a conductive layer 125 disposed on the barrier layer 126. The barrier layer 126 may include a metal nitride, and according to an example embodiment, the barrier layer 126 may include titanium nitride (TiN). The conductive layer 125 may include a metal material, and according to an example embodiment, the conductive layer 125 may include copper (Cu). The barrier layer 126 may be disposed on side and bottom surfaces of the lower interconnection layers M2, and the conductive layer 125 may be surrounded by the barrier layer 126. When the lower interconnection layers M2 include the interconnection portion L2 and the via portion V2, the barrier layer 126 may not be disposed on a boundary between the interconnection portion L2 and the via portion V2.

Coplanar surfaces of the lower insulating layer 120 and the lower interconnection layers M2 may form an upper surface of the lower structure LS, and the upper structure US may be disposed on the upper surface of the lower structure LS. The upper structure US may be the same as the upper structure US of FIGS. 1 to 3.

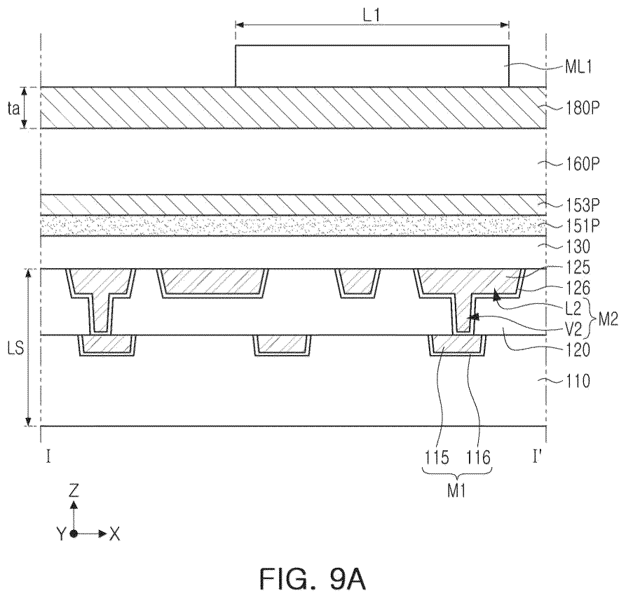

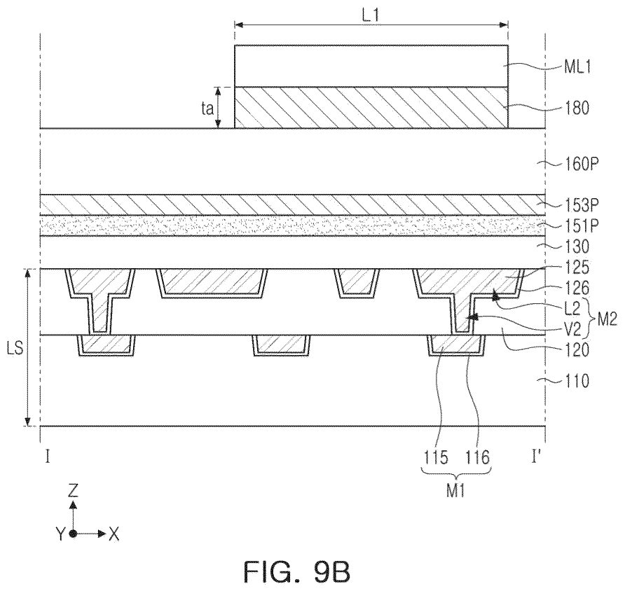

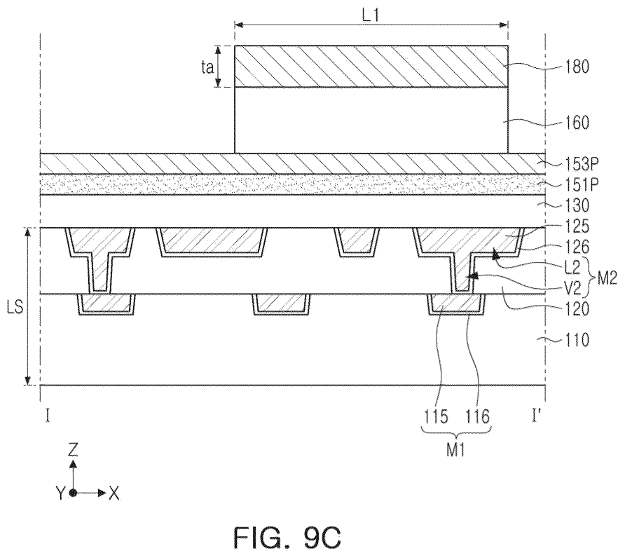

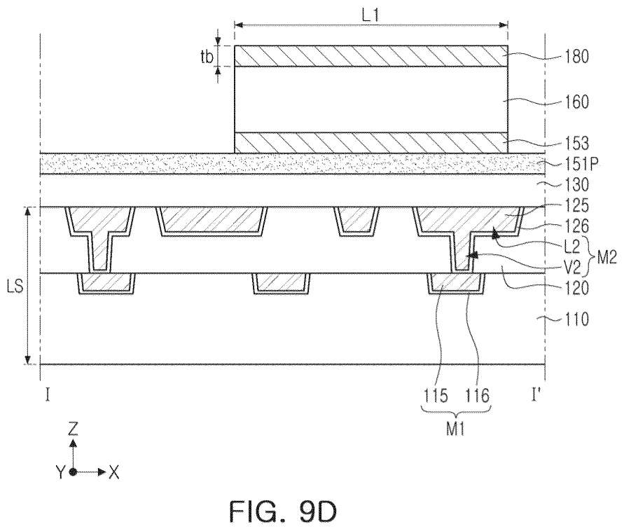

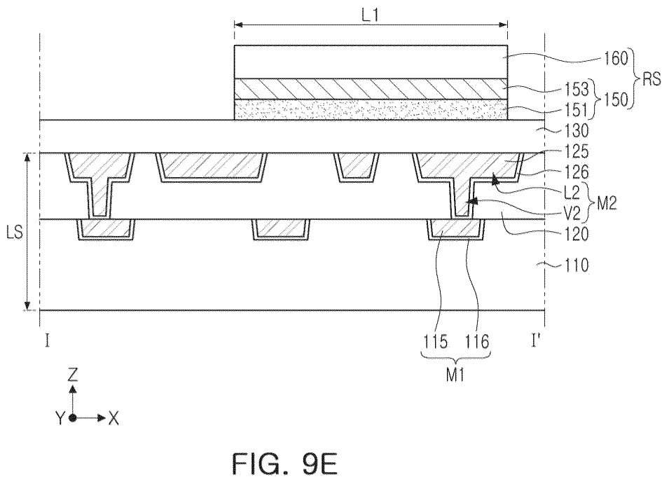

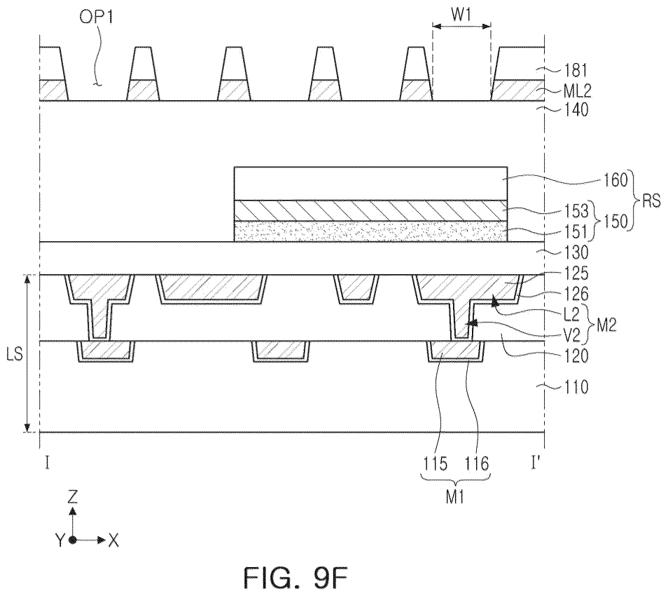

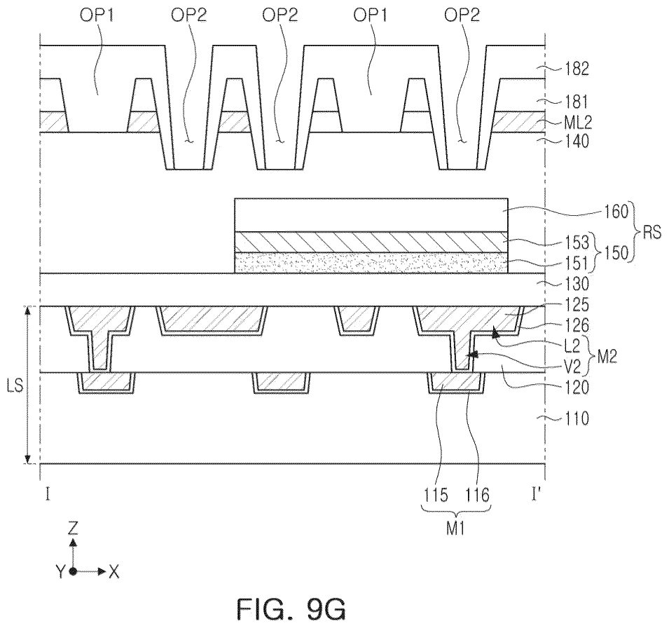

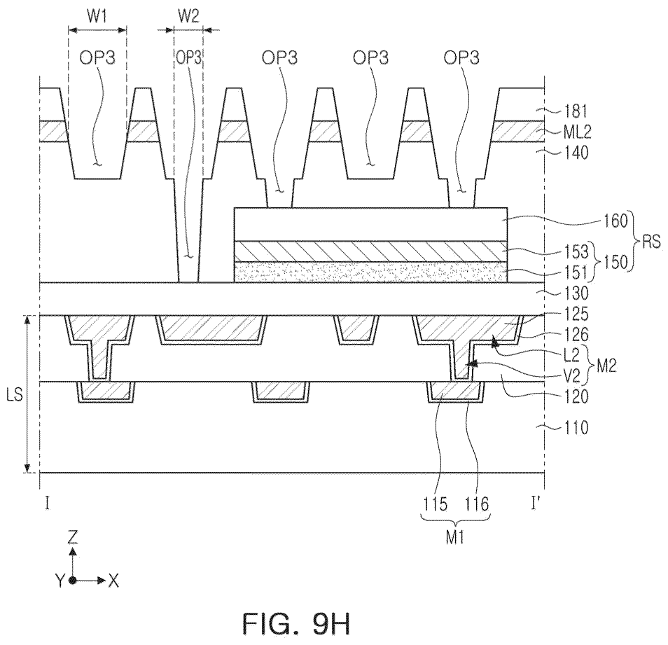

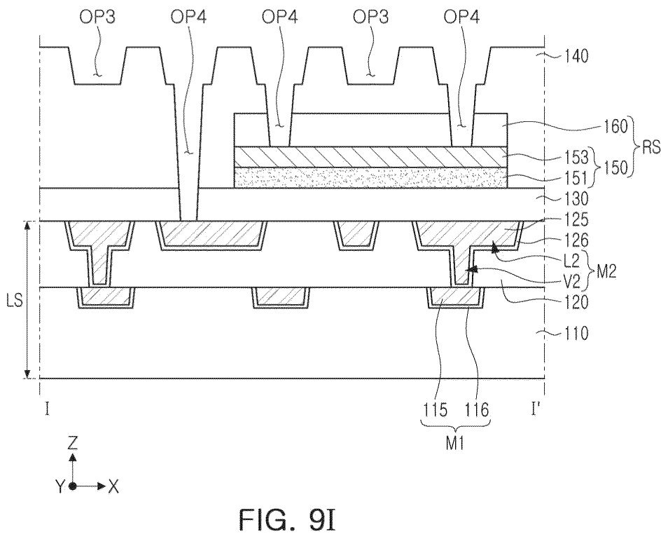

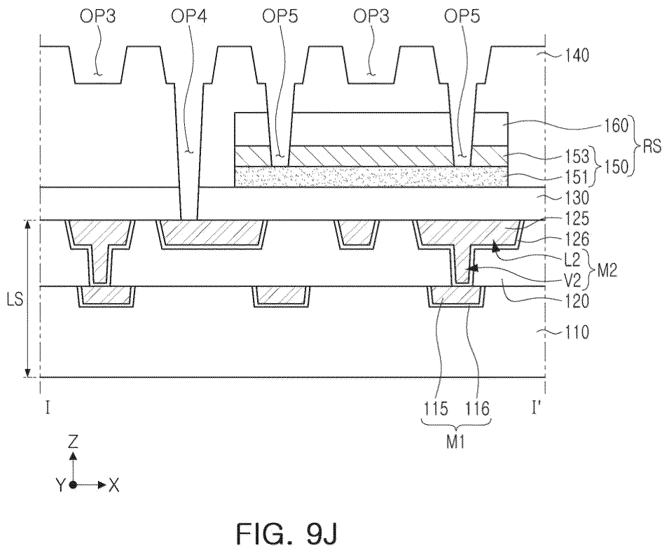

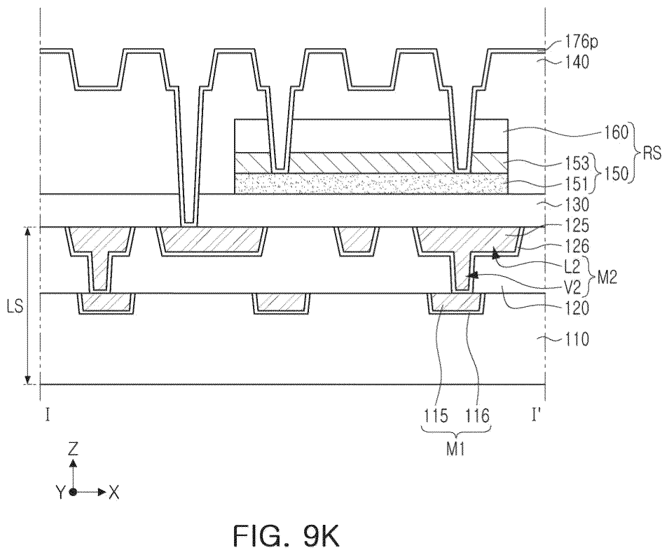

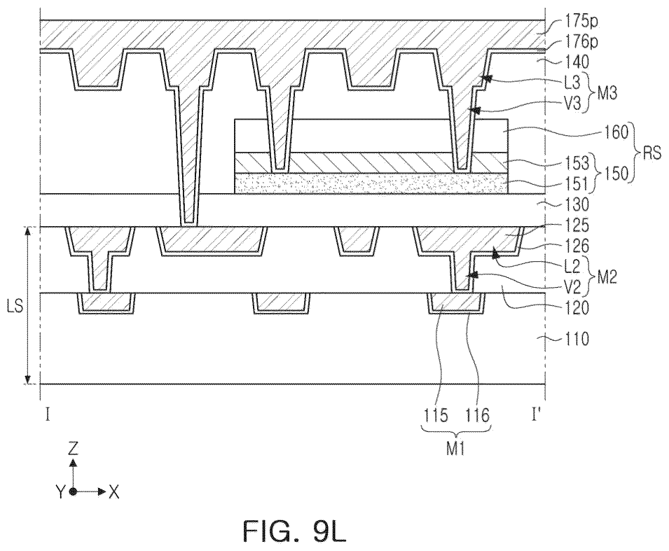

Next, a method for manufacturing a semiconductor device 100 according to an example embodiment will be described with reference to FIGS. 1 and 9A to 9L. FIGS. 9A to 9L may be cross-sectional views conceptually illustrating regions taken along line I-I′ of FIG. 1.

Referring to FIG. 9A, a lower structure LS may be formed, a base layer 130 covering the lower structure LS may be formed, preliminary resistance layers 151P, 153P, and 160P may be formed on the base layer 130, and a first mask layer 180P may be formed.

Specifically, a lower structure LS may be formed, and a base layer 130 may be formed thereon. The base layer 130 may be formed by depositing at least one of an oxide, a nitride, a carbide, or an oxynitride to entirely cover an upper surface of the lower structure LS, and may be formed of silicon oxide, silicon oxynitride, SiOC, SiCOH, SiCN, or a combination thereof.

Preliminary resistance layers 151P, 153P, and 160P for forming a resistance structure RS on the base layer 130 may be formed.

For the preliminary resistance layers 151P, 153P, and 160P, a first preliminary conductive layer 151P forming a first resistance conductive layer 151 may be deposited, and a second preliminary conductive layer 153P forming a second resistance conductive layer 153 may be deposited on the first preliminary conductive layer 151P.

The first preliminary conductive layer 151P and the second preliminary conductive layer 153P may be formed by depositing them to a first thickness t1 and a second thickness t2, respectively, on the entire upper surface of the base layer 130. The first preliminary conductive layer 151P may be formed by depositing tantalum nitride, and the second preliminary conductive layer 153P may be formed by depositing titanium nitride.

A preliminary protective layer 160P forming a protective layer 160 may be formed on the second preliminary conductive layer 153P.

The preliminary protective layer 160P may be formed by depositing the same material as the base layer 130, may include at least one of an oxide, a nitride, a carbide, or an oxynitride, may include silicon oxide, silicon oxynitride, SiOC, SiCOH, SiCN, or a combination thereof, and may preferably be formed by depositing SiCN to have a third thickness.

A first mask layer 180P may be formed on the preliminary protective layer 160P, and a mask pattern ML1 for patterning the first mask layer 180P may be formed on the first mask layer 180P. The mask pattern ML1 may be disposed to have a shape of a first length L1 and an area corresponding thereto only in a region in which the resistance structure RS is formed, by patterning the same through photo etching, and a remaining portion may be removed.

The first mask layer 180P may include the same conductive material as the second preliminary conductive layer 153P, but is not limited thereto. For example, the first mask layer 180P may include titanium nitride, but may also include tungsten, different from the second preliminary conductive layer 153P.

When the first mask layer 180P includes the same conductive material as the second preliminary conductive layer 153P, the first mask layer 180P may be formed to have an initial thickness ta, greater than the second preliminary conductive layer 153P.

As illustrated in FIG. 9B, the first mask layer 180P exposed downward by etching the mask pattern ML1 may be removed to form a hard mask pattern 180. The hard mask pattern 180 may have the initial thickness ta, and may be patterned to have a first length L1 to have an area, equal to an area of the resistance structure RS. When the hard mask pattern 180 is formed, the upper mask pattern ML1 may be removed.

As illustrated in FIG. 9C, the lower preliminary protective layer 160P may be etched with respect to the hard mask pattern 180 to form a protective layer 160. The protective layer 160 may have a third thickness t3, and may be patterned to have a first length L1 to have an area, equal to the area of the resistance structure RS.

As illustrated in FIG. 9D, the second preliminary conductive layer 153P may be etched with respect to the hard mask pattern 180 to form a second resistance conductive layer 153. The second resistance conductive layer 153 may have a second thickness t2, and may be patterned to have a first length L1 to have an area, equal to the area of the resistance structure RS below the protective layer 160.

In this case, when the hard mask pattern 180 and the second resistance conductive layer 153 may be formed of the same titanium nitride, the hard mask pattern 180 may also be etched together such that a thickness of the hard mask pattern is reduced from an initial thickness ta to an intermediate thickness tb. When the hard mask pattern 180 is formed of a different material from the second resistance conductive layer 153, the initial thickness ta may be maintained.

Next, as illustrated in FIG. 9E, the first preliminary conductive layer 151P may be etched with respect to the hard mask pattern 180 to form a first resistance conductive layer 151. The first resistance conductive layer 151 may have a first thickness t1 below the second resistance conductive layer 153, and may be patterned to a first length L1 to have an area, equal to the area of the resistance structure RS.

When the resistance structure RS having the first resistance conductive layer 151, the second resistance conductive layer 153, and the protective layer 160 and having a predetermined area is manufactured, the hard mask pattern 180 in an upper portion may be removed by cleaning. In this case, when the hard mask pattern 180 and the second resistance conductive layer 153 are formed of the same material, the hard mask pattern 180 and the second resistance conductive layer 153 may be etched together such that a recessed portion RP is partially formed on a side surface of the second resistance conductive layer 153, as in FIG. 7, but is not limited thereto.

Referring to FIG. 9F, an interlayer insulating layer 140 covering the resistance structure RS and the base layer 130 may be formed. The interlayer insulating layer 140 may be formed by depositing a low-κ dielectric or an ultra-low-κ dielectric (ULK), may include at least one of an oxide, a nitride, or an oxynitride, and may be formed by depositing silicon oxide, silicon oxynitride, SiOC, SiCOH, or a combination thereof.

Upper hard mask patterns ML2 may be formed on the interlayer insulating layer 140. The upper hard mask patterns ML2 may be patterned to expose a region in which each of the upper interconnection layers M3 of FIG. 1 is formed. Mask patterns 181 for patterning the upper hard mask patterns ML2 may be further formed on the upper hard mask patterns ML2. The mask patterns 181 may include silicon oxide, silicon nitride, silicon oxynitride, or the like, and the upper hard mask patterns ML2 may include the same material as the hard mask patterns 180.

As illustrated in FIG. 1, when five upper interconnection patterns M31 to M35 are disposed on an upper surface of a semiconductor device 100, five first openings OP1 exposing an upper surface of the interlayer insulating layer 140, in a region in which the upper interconnection patterns M31 to M35 are formed between the upper hard mask patterns ML2, may be formed. In this case, a lower width W1 of a first opening OP1 may be the same as a pattern width W1 of an interconnection pattern (M31 to M35).

Referring to FIG. 9G, second openings OP2 extending from a portion of the first openings OP1 between the upper hard mask patterns ML2 may be formed.

Specifically, an upper protective layer 182 covering the upper hard mask patterns ML2 may be further formed. A portion of the first openings OP1 of the upper protective layer 182 may be exposed, at least a portion of the exposed first openings OP1 may be exposed, and the interlayer insulating layer 140 may be etched through the exposed first openings OP1 to form second openings OP2.

Specifically, the upper protective layer 182 may be formed to expose a portion of the first openings OP1 corresponding to a second upper interconnection pattern M32, a third upper interconnection pattern M33, and a fifth upper interconnection pattern M35, including a via portion V3.

A region of the first openings OP1 exposed in the upper protective layer 182 may have a width, narrower than a width W1 of a lower end of the first openings OP1, and may be the same as a width W2 of an upper portion of the via portion V3. In this case, the second opening OP2 may be formed to expose a central region of the first opening OP1.

The second openings OP2 may be etched to the same depth as each other, and formed to be spaced apart from the upper surface of the protective layer 160 of the resistance structure RS by a predetermined distance. When the second openings OP2 are formed, the upper protective layer 182 may be cleaned and removed.

Referring to FIG. 9H, the interlayer insulating layer 140 may be etched through the first openings OP1 and the second openings OP2 of the upper hard mask patterns ML2 from which the upper protective layer 182 has been removed, to form third openings OP3.

First, the third openings OP3 may be etched to a depth sufficient to form the interconnection portion L3 in both the first openings OP1 and the second openings OP2. Next, the second openings OP2 may be etched to expose the upper surfaces of the protective layer 160 and the base layer 130, to form the third openings OP3, respectively. Because the interlayer insulating layer 140 should be etched at different depths, the third openings OP3 may be sequentially formed. For example, after exposing and etching the openings OP1 and OP2 to a depth corresponding to the interconnection portion L3, etching may be performed to expose only the second openings OP2 again to expose up to an upper portion of the protective layer 160 and an upper portion of the base layer 130. In this case, when etching is performed to expose only the second openings OP2, the protective layer 160 and the base layer 130 may include a different material from the interlayer insulating layer 140 and may thus have etching selectivity. Therefore, because the protective layer 160 and the base layer 130 may function as an etching stopper, etching may be completed without a separate etching stopper.

Therefore, third openings OP3 may be formed by a depth h1 of the interconnection portion L3 in regions in which the first and fourth upper interconnection patterns M31 and M34 are formed, a third opening OP3 may be formed in a depth extending to the base layer 130 in a region in which the second upper interconnection pattern M32 is formed, and third openings OP3 extending to the protective layer 160 may be formed in regions in which the third and fifth upper interconnection patterns M33 and M35 are formed, respectively.

Next, as illustrated in FIG. 9I, the base layer 130 and the protective layer 160 exposed by the third openings OP3 of the second, third, and fifth upper interconnection patterns M32, M33, and M35 may be etched to form fourth openings OP4. The fourth openings OP4 may expose upper surfaces of the lower interconnection layers M2 or an upper surface of the second resistance conductive layer 153, respectively.

As illustrated in FIG. 9J, the second resistance conductive layer 153 exposed by the fourth openings OP4 of the third and fifth upper interconnection patterns M33 and M35 may be etched to form fifth openings OP5. The fifth openings OP5 may expose an upper surface of the first resistance conductive layer 151, respectively.

Bottom surfaces of the fifth openings OP5 may expose the upper surface of the first resistance conductive layer 151, and a side surface bent from each of the bottom surfaces may expose a side surface of the second resistance conductive layer 153. When etching the second resistance conductive layer 153, the upper hard mask patterns ML2 may also be removed.

As illustrated in FIG. 9K, a preliminary barrier layer 176P may be conformally stacked on exposed side and bottom surfaces of the third openings OP3, the fourth openings OP4, and the fifth openings OP5 and an exposed upper surface of the interlayer insulating layer 140.

The preliminary barrier layer 176P may be deposited with a thickness of 3 nm to 4 nm, and may be deposited by chemical vapor deposition (CVD). The preliminary barrier layer 176P may be formed by depositing the same material as the first resistance conductive layer 151, for example, tantalum nitride, but is not limited thereto.

As illustrated in FIG. 9L, the third to fifth openings OP3, OP4, and OP5 may be filled on the preliminary barrier layer 176P, and a preliminary conductive layer 175P may be formed over the interlayer insulating layer 140 to a predetermined thickness.

When the preliminary conductive layer 175P includes copper, the copper may be plated and buried using a dual damascene method, but is not limited thereto.

Next, the semiconductor device 100 of FIGS. 1 to 3 may be manufactured by planarizing by chemical mechanical polishing (CMP) until the upper surface of the interlayer insulating layer 140 is exposed, as in FIG. 2.

According to example embodiments, because a resistance structure is included in an interconnection structure, and the resistance structure includes multiple different conductive layers, a change rate of resistance for heat may be minimized.

Because an interconnection layer connected to a resistance structure simultaneously contacts different conductive layers on side and bottom surfaces, a contact area may be expanded to minimize damage to a contact surface, and vertical and horizontal contacts may be simultaneously performed to secure structural contact stability. Therefore, defects such as short circuits, melting, or the like occurring on the contact surface may be minimized.

In addition, because an upper conductive layer among different conductive layers is partially etched to expose an upper surface of a lower conductive layer, defects of damaging a conductive layer and making a contact unstable due to penetration through a lower portion of a conductive layer by punching may be minimized.

While aspects of example embodiments have been particularly shown and described, it will be understood that various changes in form and details may be made therein without departing from the spirit and scope of the following claims.

1. A semiconductor device comprising:
a lower structure;
a base layer on the lower structure;
a resistance structure comprising a first resistance conductive layer on the base layer and a second resistance conductive layer on the first resistance conductive layer, wherein the first resistance conductive layer and the second resistance conductive layer comprise different materials;
an interlayer insulating layer on the resistance structure; and
upper interconnection layers extending downwardly from an upper surface of the interlayer insulating layer, wherein the upper interconnection layers are electrically connected to the resistance structure,
wherein each of the upper interconnection layers comprises a side surface and a bottom surface,
wherein the bottom surface of each of the upper interconnection layers is in contact with the first resistance conductive layer, and
wherein a portion of the side surface of each of the upper interconnection layers is in contact with the second resistance conductive layer.

2. The semiconductor device of claim 1, wherein a first upper interconnection layer among the upper interconnection layers comprises an interconnection portion extending downwardly from the upper surface of the interlayer insulating layer by a first depth, and a via portion extending downwardly from a lower surface of the interconnection portion by a second depth and contacting an upper surface of the first resistance conductive layer.

3. The semiconductor device of claim 2, wherein a lower end of the via portion penetrates the second resistance conductive layer to directly contact the upper surface of the first resistance conductive layer and a bottom surface of the via portion.

4. The semiconductor device of claim 1, wherein the first resistance conductive layer comprises a material having a negative slope in thermal resistance, and the second resistance conductive layer comprises a material having a positive slope in thermal resistance.

5. The semiconductor device of claim 4, wherein the first resistance conductive layer and the second resistance conductive layer have a same thickness.

6. The semiconductor device of claim 1, wherein the first resistance conductive layer comprises tantalum nitride, and the second resistance conductive layer comprises titanium nitride.

7. The semiconductor device of claim 6, wherein a thickness of the first resistance conductive layer is less than a thickness of the second resistance conductive layer.

8. The semiconductor device of claim 1, wherein an area of the first resistance conductive layer is larger than an area of the second resistance conductive layer.

9. The semiconductor device of claim 1, wherein the resistance structure further comprises at least one metal layer between the first resistance conductive layer and the second resistance conductive layer.

10. The semiconductor device of claim 1, wherein a contact area between the upper interconnection layers and the first resistance conductive layer is smaller than a contact area between the upper interconnection layers and the second resistance conductive layer.

11. The semiconductor device of claim 1, wherein the resistance structure further comprises a protective layer above the second resistance conductive layer, and
wherein the upper interconnection layer penetrates the protective layer.

12. The semiconductor device of claim 11, wherein the protective layer comprises a material, identical to a material of the base layer.

13. The semiconductor device of claim 1, wherein the upper interconnection layers comprise:
a conductive layer; and
a barrier layer on a side surface and a bottom surface of the conductive layer.

14. The semiconductor device of claim 13, wherein the barrier layer comprises a material, identical to a material of the first resistance conductive layer.

15. A semiconductor device comprising:
a base layer;
a resistance structure comprising a first resistance conductive layer on the base layer and a second resistance conductive layer on the first resistance conductive layer, wherein the first resistance conductive layer and the second resistance conductive layer comprise different materials;
an interlayer insulating layer on the resistance structure; and
upper connection structures extending downwardly from an upper surface of the interlayer insulating layer, wherein the upper connection structures are electrically connected to the resistance structure,
wherein each of the upper connection structures extends from through the second resistance conductive layer to the first resistance conductive layer, a side surface of each of the upper connection structures horizontally contacts the second resistance conductive layer, and a bottom surface of each of the upper connection structures vertically contacts the first resistance conductive layer.

16. The semiconductor device of claim 15, wherein the first resistance conductive layer comprises a material having a negative slope in thermal resistance, and the second resistance conductive layer comprises a material having a positive slope in thermal resistance.

17. The semiconductor device of claim 16, wherein the first resistance conductive layer and the second resistance conductive layer have a same thickness.

18. The semiconductor device of claim 15, wherein the first resistance conductive layer comprises tantalum nitride, and the second resistance conductive layer comprises titanium nitride.

19. The semiconductor device of claim 18, wherein a thickness of the first resistance conductive layer is less than a thickness of the second resistance conductive layer, and a slope of composite thermal resistance of the first resistance conductive layer and the second resistance conductive layer converges to 0.

20. A semiconductor device comprising:
a lower structure comprising a substrate, circuit elements, a lower insulating layer, and lower interconnection layers connected to the circuit elements;
a resistance structure comprising a first resistance conductive layer on the lower structure and a second resistance conductive layer on the first resistance conductive layer, wherein the first resistance conductive layer and the second resistance conductive layer comprise different materials;
an interlayer insulating layer on the resistance structure; and
upper interconnection layers extending downwardly from an upper surface of the interlayer insulating layer, wherein the upper interconnection layers electrically connected to the lower interconnection layers or the resistance structure,
wherein each of the upper interconnection layers comprises a side surface and a bottom surface,
wherein the bottom surface of each of the upper interconnection layers connected to the resistance structure is in contact with the first resistance conductive layer,
wherein a portion of the side surface of each of the upper interconnection layers is in contact with the second resistance conductive layer, and
wherein the bottom surface of each of the upper interconnection layers connected to the lower interconnection layers is in contact with an upper surface of each of the lower interconnection layers.

21-23. (canceled)
